(19) United States
(12) Patent Application Publication
(10) Pub. No.: US 2025/0096099 A1
(43) Pub. Date: Mar. 20, 2025

(54) SEMICONDUCTOR PACKAGE

(71) Applicant: SAMSUNG ELECTRONICS CO., LTD., SUWON-SI (KR)

(72) Inventors: JAESUN KIM, Suwon-si (KR); HEEYOUB KANG, Suwon-si (KR); EUNKYEONG PARK, Suwon-si (KR); YISEUL HAN, Suwon-si (KR)

(21) Appl. No.: 18/751,036

(22) Filed: Jun. 21, 2024

(30) Foreign Application Priority Data
Sep. 18, 2023 (KR) 10-2023-0123818

(51) Int. Cl. H01L 23/498; H01L 23/00; H01L 23/31; H01L 23/367; H01L 25/18; H10B 80/00

(52) U.S. Cl. CPC H01L 23/49838; H01L 23/3135; H01L 23/3672; H01L 23/49833; H01L 23/49866; H01L 24/16; H01L 24/32; H01L 24/73; H01L 24/48; H01L 25/18; H01L 2224/16145; H01L 2224/16238; H01L 2224/32145; H01L 2224/48145; H01L 2224/48225; H01L 2224/73204; H01L 2225/06506; H01L 2225/0651; H01L 2225/06562; H01L 2924/1431; H10B 80/00

(57) ABSTRACT

A semiconductor package may include a lower redistribution structure having a lower redistribution layer, a lower chip structure on the lower redistribution structure, the lower chip structure including a first semiconductor chip, a second semiconductor chip on the first semiconductor chip, a plurality of first posts on a side of the second semiconductor chip and electrically connected to the first semiconductor chip, and a first encapsulant covering the first semiconductor chip, the second semiconductor chip, and the plurality of first posts, a plurality of second posts on a side of the lower chip structure and electrically connected to the lower redistribution layer, a second encapsulant covering the lower chip structure and each of the plurality of second posts, connection vias passing through a portion of the second encapsulant, and electrically connected to the plurality of first posts, and an upper redistribution structure on the second encapsulant.

### CROSS-REFERENCE TO RELATED APPLICATION(S)

This application claims priority to Korean Patent Application No. 10-2023-0123818, filed on Sep. 18, 2023, in the Korean Intellectual Property Office, and all the benefits accruing therefrom, the disclosure of which is incorporated herein by reference in its entirety.

### BACKGROUND

The present inventive concept relates to a semiconductor package.

With a reduction in weight and an implementation of high performance electronic devices, the development of semiconductor packages, having a reduced size and high performance, has become of interest in the field of semiconductor packages. Technologies have been emerging to improve the reliability of high-performance semiconductor chips by shortening a signal transmission path between a plurality of chips.

### SUMMARY

An aspect of the present inventive concept provides a semiconductor package having improved reliability.

According to an aspect of the present inventive concept, there is provided a semiconductor package including a lower redistribution structure including a lower redistribution layer, a lower chip structure on the lower redistribution structure, the lower chip structure including a first semiconductor chip electrically connected to the lower redistribution layer, a second semiconductor chip on the first semiconductor chip, a plurality of first posts on at least one side of the second semiconductor chip and electrically connected to the first semiconductor chip, and a first encapsulant covering at least a portion of each of the first semiconductor chip, the second semiconductor chip, and the plurality of first posts, a plurality of second posts on the lower redistribution structure, wherein the plurality of second posts are on at least one side of the lower chip structure and electrically connected to the lower redistribution layer, a second encapsulant covering at least a portion of the lower chip structure and each of the plurality of second posts, connection vias passing through a portion of the second encapsulant covering an upper portion of the lower chip structure, wherein the connection vias respectively electrically connected to the plurality of first posts, an upper redistribution structure on the second encapsulant, the upper redistribution structure including an upper redistribution layer and upper redistribution vias electrically connecting the upper redistribution layer and the connection vias to each other, an upper chip structure on the upper redistribution structure and electrically connected to the upper redistribution layer, and external connection conductors on the lower redistribution structure and electrically connected to the lower redistribution layer.

According to another aspect of the present inventive concept, there is provided a semiconductor package including a lower redistribution structure, a lower chip structure including a first semiconductor chip on the lower redistribution structure, a second semiconductor chip on the first semiconductor chip, a first encapsulant surrounding the second semiconductor chip, and a plurality of first posts passing through the first encapsulant, the plurality of first posts electrically connected to the first semiconductor chip, a second encapsulant on the lower redistribution structure and surrounding the lower chip structure, a plurality of second posts passing through the second encapsulant, wherein the plurality of second posts are electrically connected to the lower redistribution structure, an upper redistribution structure on the second encapsulant, and an upper chip structure mounted on the upper redistribution structure. The plurality of first posts may provide a transmission path for a signal between the lower chip structure and the upper chip structure.

According to another aspect of the present inventive concept, there is provided a semiconductor package including a lower redistribution structure, a lower chip structure including a plurality of semiconductor chips on the lower redistribution structure and a plurality of first posts on a lowermost semiconductor chip, among the plurality of semiconductor chips, wherein the plurality of first posts are spaced apart from chips other than the lowermost semiconductor chip, a plurality of second posts on the lower redistribution structure, an encapsulant covering at least a portion of each of the lower chip structure and the plurality of second posts, and an upper chip structure on the encapsulant and electrically connected to the plurality of first posts and second posts. A level of an uppermost end of each of the plurality of first posts may be lower than a level of an uppermost end of each of the plurality of second posts.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a cross-sectional view illustrating a semiconductor package, according to an embodiment of the present inventive concept.

FIG. 1B is a plan view illustrating the semiconductor package in FIG. 1A;

FIG. 2 is a cross-sectional view illustrating an upper chip structure applicable to the semiconductor package of FIG. 1A, according to an embodiment;

FIG. 3 is a cross-sectional view illustrating a semiconductor package, according to an embodiment of the present inventive concept;

FIG. 4 is a cross-sectional view illustrating a semiconductor package, according to an embodiment of the present inventive concept;

FIG. 5 is a cross-sectional view illustrating a semiconductor package, according to an embodiment of the present inventive concept;

FIG. 6 is a cross-sectional view illustrating a semiconductor package, according to an embodiment of the present inventive concept;

FIG. 7 is a cross-sectional view illustrating a semiconductor package, according to an embodiment of the present inventive concept;

FIGS. 8A to 8C are cross-sectional views illustrating a process of manufacturing a lower chip structure of a semiconductor package, according to an embodiment of the present inventive concept; and

FIGS. 9A to 9E are cross-sectional views illustrating a process of manufacturing a semiconductor package, according to an embodiment of the present inventive concept.

### DETAILED DESCRIPTION

Hereinafter, preferred example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which a component is actually arranged and oriented in space.

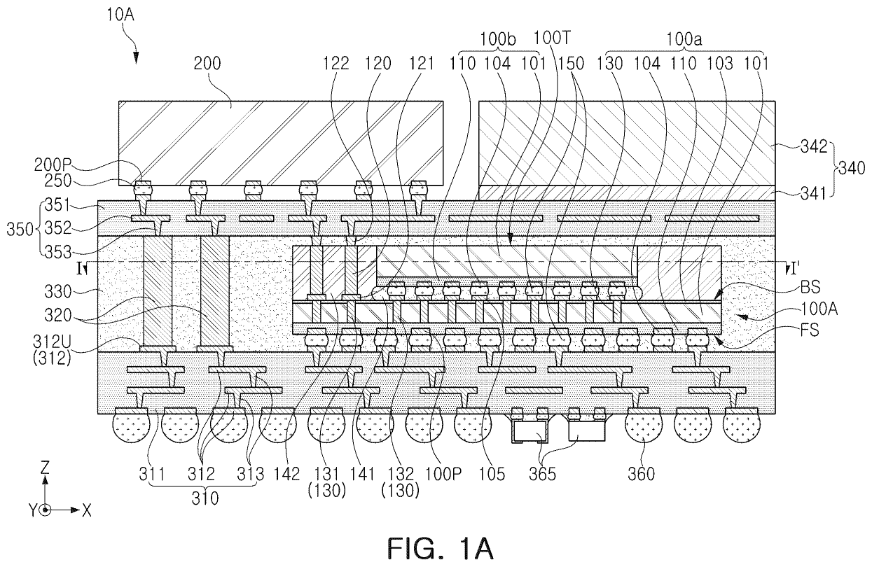

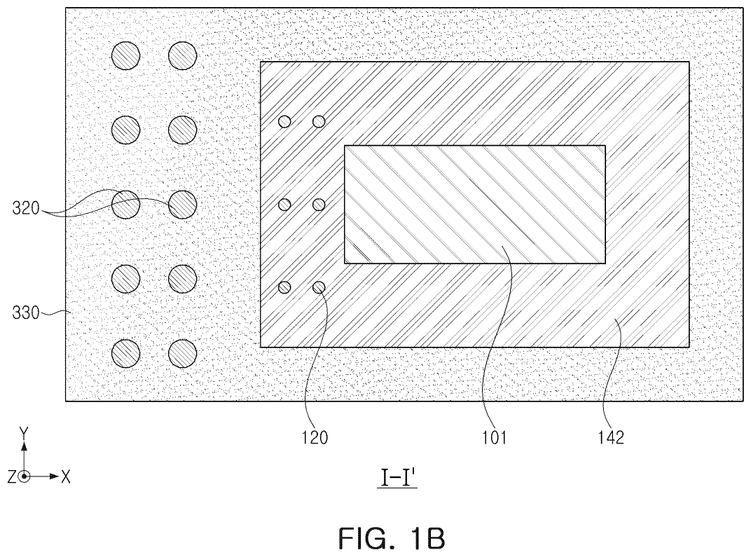

FIG. 1A is a cross-sectional view illustrating a semiconductor package, according to an embodiment of the present inventive concept.

FIG. 1B is a plan view illustrating a cross-section taken along line I-I′ of FIG. 1A.

Referring to FIGS. 1A and 1B, a semiconductor package 10A may include a lower chip structure 100A, an upper chip structure 200, a lower redistribution structure 310, a plurality of second posts 320, a second encapsulant 330, and an upper redistribution structure 350. Referring to FIGS. 1A and 1B, the semiconductor package 10A, according to an embodiment may include a heat dissipation member 340 and external connection conductors 360.

In various embodiments, the lower chip structure 100A may be disposed on the lower redistribution structure 310, and may include a plurality of semiconductor chips 100a and 100b stacked vertically (for example, in a Z-axis direction). At least a portion (for example, “100a”) of the plurality of semiconductor chips 100a and 100b may include through-vias 130, electrically connecting the plurality of semiconductor chips 100a and 100b to each other. The through-vias 130 may extend through a substrate 101. The plurality of semiconductor chips 100a and 100b may be chiplets, included in a multichip module (MCM). The plurality of semiconductor chips 100a and 100b may include a central processing unit (CPU), a graphics processing unit (GPU), a field programmable gate array (FPGA), a digital signal processor (DSP), a cryptographic processor, a microprocessor, a microcontroller, an analog-digital converter, an application-specific integrated circuit (ASIC), a volatile memory, a non-volatile memory, an input/output (I/O) circuit, an analog circuit, a serial-parallel conversion circuit, and the like.

In various embodiments, the lower chip structure 100A may include a first semiconductor chip 100a and a second semiconductor chip 100b. The first semiconductor chip 100a may include a processor circuit, and the second semiconductor chip 100b may include at least one of an input/output circuit, an analog circuit, a memory circuit, or a serial-parallel conversion circuit for the processor circuit.

In various embodiments, the lower chip structure 100A may have a different number of semiconductor chips 100a and 100b that shown in FIG. 1A, where the number of semiconductor chips may greater than two. Additional semiconductor chips may include an input/output circuit, an analog circuit, a memory circuit, or a serial-parallel conversion circuit different from the second semiconductor chip 100b, or a processor circuit in addition to the first semiconductor chip 100a.

In various embodiments, the lower chip structure 100A may include a first encapsulant 142 covering at least a portion of each of the first semiconductor chip 100a and the second semiconductor chip 100b. In various embodiments, an underfill portion 141 may be formed between the first semiconductor chip 100a and the second semiconductor chip 100b.

In various embodiments, the first semiconductor chip 100a and the second semiconductor chip 100b may each include a substrate 101. The first semiconductor chip 100a may include, an upper protective layer 103, an upper pad 105, a circuit layer 110, a lower pad 104, and/or a through-via 130. The second semiconductor chip 100b may include a circuit layer 110 and/or a lower pad 104.

In various embodiments, the substrate 101 may include, for example, a semiconductor material, such as silicon (Si) or germanium (Ge), or a compound semiconductor material, such as silicon carbide (SiC), gallium arsenide (GaAs), indium arsenide (InAs), or indium phosphatase (InP). The substrate 101 may have a silicon on insulator (SOI) structure. The substrate 101 may have a conductive region, for example, a well doped with impurities, or an active surface doped with impurities and an inactive surface opposite thereto. The substrate 101 may include various isolation structures, such as a shallow trench isolation (STI) structure.

In various embodiments, the first semiconductor chip 100a may have a front surface FS and a back surface BS, opposing each other with a thickness therebetween. The front surface FS of the first semiconductor chip 100a may be a surface adjacent to the active surface of the substrate 101, and may refer to a lower surface of the circuit layer 110. The back surface BS of the first semiconductor chip 100a, may be a surface adjacent to the inactive surface of the substrate 101, and may refer to an upper surface of the upper protective layer 103 of the substrate 101.

In various embodiments, the upper protective layer 103 may be formed on the inactive surface of the substrate 101, and may protect the substrate 101. The upper protective layer 103 may be formed of an insulating layer, such as a silicon oxide film, a silicon nitride film, or a silicon oxynitride film, but a material of the upper protective layer 103 is not limited to the above-described materials. For example, the upper protective layer 103 may be formed of a polymer, such as polyimide (PI). In various embodiments, a lower protective layer may be further formed on the lower surface of the circuit layer 110.

In various embodiments, the upper pad 105 may be disposed on the upper protective layer 103, where the upper pad 105 may include, for example, at least one of aluminum (Al), copper (Cu), nickel (Ni), tungsten (W), platinum (Pt), or gold (Au). The lower pad 104 may be disposed on a lower portion of the circuit layer 110, and may include, for example, at least one of aluminum (Al), copper (Cu), nickel (Ni), tungsten (W), platinum (Pt), or gold (Au), where the lower pad 104 may be the same material as the upper pad 105. However, a material of each of the upper pad 105 and lower pad 104 are not limited to the above-described materials.

In various embodiments, the circuit layer 110 may be disposed on the active surface of the substrate 101, and may include various types of devices. For example, the circuit layer 110 may include a FET, such as a planar field effect transistor (FET) or a FinFET, a memory device, such as flash memory, dynamic random access memory (DRAM), static random access memory (SRAM), electrically erasable memory (EEPROM), phase-change random access memory (PRAM), magneto-resistive random access memory (MRAM), ferroelectric random access memory (FeRAM), or resistive random access memory (RRAM), a logic device, such as AND, OR, or NOT, and various active and/or passive devices, such as a system large scale integration (LSI), a CMOS imaging sensor (CIS), and a micro-electro-mechanical system (MEMS).

In various embodiments, the circuit layer 110 may include an interconnection line structure electrically connected to the above-described devices, and an interlayer insulating layer surrounding the interconnection line structure. The interlayer insulating layer may include silicon oxide or silicon nitride. The interconnection line structure may include a multilayer interconnection line and/or a vertical contact. The interconnection line structure may connect devices of the circuit layer 110 to each other, connect the devices to the conductive region of the substrate 101, and/or connect the devices to the through-vias 130.

In various embodiments, the through-vias 130 may pass through the substrate 101 in a vertical direction (for example, Z-axis direction) and may provide an electrical path, connecting the upper pad 105 and the lower pads 104 to each other. The through-vias 130 may include a conductive plug and a barrier film surrounding the conductive plug. The conductive plug may include a metal, such as tungsten (W), titanium (Ti), aluminum (Al), or copper (Cu). The conductive plug may be formed using a plating process, a PVD process, or a CVD process. The barrier film may include an insulating barrier film and/or a conductive barrier film. The insulating barrier film may be formed of an oxide film, a nitride film, a carbonization film, a polymer, or combinations thereof. The conductive barrier film may be disposed between the insulating barrier film and the conductive plug. The conductive barrier film may include a metal compound, such as tungsten nitride (WN), titanium nitride (TiN), or tantalum nitride (TaN), for example. The barrier film may be formed using a PVD process or a CVD process. The through-vias 130 may include first through-vias 131, not overlapping the second semiconductor chip 100b in the vertical direction (for example, Z-axis direction), and second through-vias 132 disposed below the second semiconductor chip 100b. The first through-vias 131 and the second through-vias 132 may be disposed to be spaced apart from each other in a horizontal direction (for example, X-axis direction).

In various embodiments, the lower chip structure 100A may include a plurality of first posts 120 disposed around the second semiconductor chip 100b.

In various embodiments, a plurality of second posts 320 may pass through a second encapsulant 330 and electrically connect the first semiconductor chip 100a and an upper redistribution layer 352 to each other.

In various embodiments, the plurality of first posts 120 may extend in the vertical direction (for example, Z-axis direction) within the first encapsulant 142. An upper surface of each of the plurality of first posts 120 may be exposed at a surface of the first encapsulant 142 and be electrically connected to an upper redistribution via 353 of the upper redistribution structure 350 via connection vias 122. The plurality of first posts 120 may have a cylindrical shape, but the present inventive concept is not limited thereto.

In various embodiments, the plurality of first posts 120 may include copper (Cu), nickel (Ni), titanium (Ti), lead (Pb), aluminum (Al), silver (Ag), gold (Au), platinum (Pt), or alloys thereof. In an example embodiment, the plurality of first posts 120 may include copper (Cu). Connection pads 121 may be disposed between the plurality of first posts 120 and the through-vias 130, and the plurality of first posts 120 and the through-vias 130 may be respectively electrically connected to each other via the connection pads 121. The connection pads 121 may be disposed on the back surface BS of the first semiconductor chip 100a. A diameter of each of the plurality of first posts 120 may be greater than a diameter of each of the through-vias 130. A plurality of through-vias 130 may be connected to a single first post 120. At least a portion of the plurality of first posts 120 may be disposed to overlap with the upper chip structure 200 in a direction (for example, X-axis direction), perpendicular to an upper surface of the lower chip structure 100A. One or more first posts 120 may be positioned beneath the upper chip structure 200, where the lower redistribution structure 310 may be electrically connected to the upper chip structure 200 through the through-vias 130 and first posts 120.

In various embodiments, the plurality of first posts 120 may be electrically connected to the first semiconductor chip 100a via the through-vias 130, and may be electrically connected to the upper chip structure 200 via the connection vias 122 and the upper redistribution layer 352. The plurality of first posts 120 may provide a transmission path for a signal to the upper chip structure 200. Here, the “signal” may refer to all types of signals except a power signal, for example, a data signal, a command signal, an address signal, a ground signal, and the like.

In various embodiments, the first encapsulant 142 may cover at least a portion of each of the first semiconductor chip 100a, the second semiconductor chip 100b, and the plurality of first posts 120. The first encapsulant 142 may cover an upper surface of the first semiconductor chip 100a, and the first encapsulant 142 may cover a side surface of each of the second semiconductor chip 100b and the plurality of first posts 120. The first encapsulant 142 may expose an upper surface of each of the plurality of first posts 120. An upper surface of the first encapsulant 142 may be substantially coplanar with an upper surface of the lower chip structure 100A and upper surfaces of the plurality of first posts 120.

In various embodiments, the first encapsulant 142 may include an insulating resin, for example, a thermosetting resin, such as an epoxy resin, a thermoplastic resin, such as polyimide, or a prepreg, an Ajinomoto build-up film (ABF), FR-4, bismaleimide-triazine (BT), or an epoxy molding compound (EMC). The first encapsulant 142 may include a filler dispersed in the insulating resin.

In various embodiments, connection bumps 150 may be disposed below the first semiconductor chip 100a and between the first semiconductor chip 100a and the second semiconductor chip 100b. The connection bumps 150 may be in the form of a combination of a pillar (or under-bump metal) and a ball. The pillar may include copper (Cu) or an alloy of copper (Cu), and the ball may include a low melting point metal, for example, tin (Sn) or an alloy (Sn—Ag—Cu) including tin (Sn). In some embodiments, the connection bumps 150 may include only a pillar or ball.

In various embodiments, the lower chip structure 100A may include first connection terminals 100P electrically connected to a lower redistribution layer 312, on the lower redistribution structure 310. The first connection terminals 100P may be connected to the lower redistribution layer 312 via the connection bumps 150 disposed between the lower chip structure 100A and the lower redistribution structure 310. The connection bumps 150 may be between and in electrical contact with the redistribution pads 312U and the first connection terminals 100P.

In various embodiments, the upper chip structure 200 may be disposed on the upper redistribution structure 350, and may be electrically connected to the lower redistribution layer 312 via the plurality of second posts 320. The upper chip structure 200 may include second connection terminals 200P electrically connected to the plurality of second posts 320, where the second connection terminals 200P may be electrically connected to the plurality of second posts 320 via upper connection bumps 250 disposed between the upper chip structure 200 and the plurality of second posts 320, where the upper connection bumps 250 may be between the upper chip structure 200 and the upper redistribution structure 350. The upper chip structure 200 may be electrically connected to the lower chip structure 100A via the lower redistribution layer 312 and the plurality of second posts 320. An insulating material layer surrounding the upper connection bumps 250, may be formed below the upper chip structure 200.

In various embodiments, the upper chip structure 200 may be positioned to vertically overlap at least some of the second posts320, among the plurality of second posts 320. In addition, the upper chip structure 200 may be laterally offset from the lower chip structure 100A in the horizontal direction (for example, direction of X-axis), so as to expose at least a portion of the lower chip structure 100A in the vertical direction (for example, direction of Z-axis), such that the upper chip structure 200 and the lower chip structure 100A may be staggered. The upper chip structure 200 may be located to one side of the heat dissipation member 340, where the heat dissipation member 340 may be located above the lower chip structure 100A.

In various embodiments, the upper chip structure 200 may include a semiconductor wafer and a semiconductor wafer integrated circuit (IC) including a semiconductor element such as silicon or germanium, or a compound semiconductor such as silicon carbide (SiC), gallium arsenide (GaAs), indium arsenide (InAs), and indium phosphide (InP). The upper chip structure 200 may be a bare semiconductor chip without a bump or interconnection line layer, but the present inventive concept is not limited thereto.

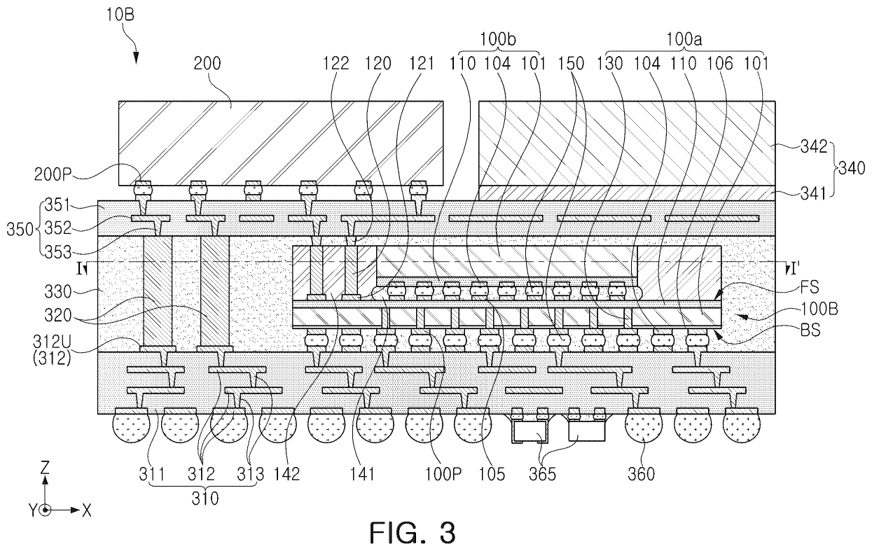

In various embodiments, the upper chip structure 200 may be a packaged-type semiconductor chip. An integrated circuit may be a logic circuit (or “logic chip”), such as a CPU, a GPU, an FPGA, an application processor (AP), a digital signal processor, a cryptographic processor, a microprocessor, a microcontroller, an analog-to-digital converter, or an ASIC, or a memory circuit (or “memory chip”) including a volatile memory, such as a dynamic RAM (DRAM) or a static RAM (SRAM), and a non-volatile memory such as a phase change RAM (PRAM), a magnetic RAM (MRAM), a resistive RAM (RRAM), or a flash memory. The lower chip structure 100A and the upper chip structure 200 may include different types of integrated circuits. For example, the lower chip structure 100A may include a logic circuit, and the upper chip structure 200 may include a memory circuit. In various embodiments, each of the lower chip structure 100A and the upper chip structure 200 may be a semiconductor package structure including a plurality of semiconductor chips, which will be described below with reference to FIGS. 3A to 3C.

In various embodiments, the lower redistribution structure 310 may include a support substrate on which the lower chip structure 100A is mounted, and may include a lower insulating layer 311, lower redistribution layers 312, and a lower redistribution via 313.

In various embodiments, the lower insulating layer 311 may include an insulating resin. The insulating resin may include a thermosetting resin, such as an epoxy resin, a thermoplastic resin, such as polyimide, or a resin in which such resins are impregnated with an inorganic filler, for example, a prepreg, an ABF, FR-4, or BT. For example, the lower insulating layer 311 may include a photosensitive resin such as a photo-imageable dielectric (PID). The lower insulating layer 311 may include a plurality of insulating layers stacked in the vertical direction (Z-axis direction). Depending on the process, the plurality of insulating layers may have unclear boundaries therebetween.

In various embodiments, the lower redistribution layer 312 may be disposed on or within the lower insulating layer 311, and may redistribute the first connection terminals 100P of the lower chip structure 100A, where the lower redistribution layer 312 may form an electrical connection through the lower insulating layer 311. The lower redistribution layer 312 may include, for example, a metal including copper (Cu), aluminum (Al), silver (Ag), tin (Sn), gold (Au), nickel (Ni), lead (Pb), titanium (Ti), or alloys thereof.

In various embodiments, the lower redistribution layer 312 may perform various functions depending on the design, where for example, the lower redistribution layer 312 may include a ground pattern, a power pattern, and/or a signal pattern. The lower redistribution layer 312 may include more or fewer redistribution layers than those illustrated in the drawings. The lower redistribution layer 312 may include redistribution pads 312U disposed on an upper surface of the lower redistribution structure 310. The redistribution pads 312U may be electrically connected to the plurality of second posts 320 and the first connection terminals 100P of the lower chip structure 100A.

In various embodiments, the lower redistribution via 313 may vertically extend within the lower insulating layer 311 and be electrically connected to the lower redistribution layer 312. For example, the lower redistribution via 313 may connect lower redistribution layers 312 on different levels to each other. The lower redistribution via 313 may include a signal via, a ground via, and/or a power via.

In various embodiments, the lower redistribution via 313 may include, for example, a metal material including copper (Cu), aluminum (Al), silver (Ag), tin (Sn), gold (Au), nickel (Ni), lead (Pb), titanium (Ti), or alloys thereof. The lower redistribution via 313 may be a filled via in which a via hole is filled with a metal material or a conformal via in which a metal material extends along an inner wall of a via hole.

In various embodiments, the plurality of second posts 320 may be disposed on redistribution pads 312U on the upper surface of the lower redistribution structure 310, where the redistribution pads 312U may be on and cover a portion of the lower substrate 311. The plurality of second posts 320 may extend in a direction (for example, Z-axis direction), perpendicular to the upper surface of the lower redistribution structure 310, such that the second posts 320 extend away from the upper surface of the lower redistribution structure 310. The plurality of second posts 320 may pass through at least a portion of the second encapsulant 330. The plurality of second posts 320 may be spaced apart from the lower chip structure 100A in the horizontal direction (for example, X-axis direction), where a portion of thesecond encapsulant 330 may be interposed between the lower chip structure 100A and the second posts 320.

In various embodiments, the plurality of second posts 320 may be electrically connected to the lower redistribution layer 312 and may be electrically connected to the upper chip structure 200 via the upper redistribution layer 352. The plurality of second posts 320 may provide a transmission path for a power signal to the upper chip structure 200. A diameter of each of the plurality of second posts 320 may be greater than or equal to a diameter of each of the plurality of first posts 120. The diameter of each of the plurality of first posts 120 may be about 30 micrometers (μm) or less, for example, about 30 μm or less, or about 10 μm to about 30 μm, or about 20 μm to about 30 μm, or about 25 μm to about 30 μm, or the like, but the present inventive concept is not limited thereto. The diameter of each of the plurality of second posts 320 may be 30 μm or more, for example, about 30 μm or more, or about 30 μm to about 70 μm, or about 30 μm to about 60 μm, or about 30 μm to about 45 μm, or the like, but the present inventive concept is not limited thereto.

In various embodiments, a length of each of the plurality of second posts 320 in the vertical direction (for example, Z-axis direction) may be greater than a length of each of the plurality of first posts 120 in the vertical direction. The plurality of first posts 120, shorter than the plurality of second posts 320, may be utilized, thereby shortening a signal transmission path between the lower chip structure 100A and the upper chip structure 200.

In various embodiments, the plurality of second posts 320 may have features similar to those of the plurality of first posts 120, and thus the detailed description of the first posts 120 may be applied to the plurality of second posts 320. The number of first posts 120 and second posts 320 is not limited to the number of those illustrated in the drawings.

In various embodiments, the second encapsulant 330 may be disposed on the lower redistribution structure 310, and may cover at least a portion of each of the lower redistribution structure 310, the lower chip structure 100A, and the plurality of second posts 320. The second encapsulant 330 may be disposed on an upper surface 100T of the lower chip structure 100A. The upper surface 100T of the lower chip structure 100A may be coplanar with an upper surface of the first encapsulant 142 and the first semiconductor chip 100a. A portion of the second encapsulant 330 may be between the lower chip structure 100A and the upper redistribution structure 350, where the second encapsulant 330 may surround the lower chip structure 100A. The second encapsulant 330 may be in contact with at least a portion of each of the upper surfaces of the plurality of first posts 120, and an upper surface of the second semiconductor chip 100b. The second encapsulant 330 may have features similar to those of the first encapsulant 142, and thus the detailed description of the first encapsulant 142 may be applied to the second encapsulant 330. In an example embodiment, the second encapsulant 330 may include an insulating resin in which a filler is dispersed, and an average diameter of the filler of the second encapsulant 330 may be greater than or equal to an average diameter of the filler of the first encapsulant 142, but the inventive concept is not limited thereto.

In various embodiments, the connection vias 122 may pass through a portion of the second encapsulant 330 disposed between the lower chip structure 100A and the upper redistribution structure 350. Lower surfaces of the connection vias 122 may be electrically connected to the upper surfaces of the plurality of first posts 120, and upper surfaces of the connection vias 122 may be electrically connected to a lower surface of the upper redistribution via 353. The connection vias 122 may have a downwardly tapered shape toward the lower chip structure 100A, where a width of a lower surface of each of the connection vias 122 in the horizontal direction (for example, X-axis direction) may be less than a width of an upper surface of each of the plurality of first posts 120 in the horizontal direction.

In various embodiments, the upper redistribution structure 350 may be disposed on the second encapsulant 330, and may be in contact with the plurality of second posts 320, the second encapsulant 330, and the connection vias 122. The upper redistribution structure 350 may form a support substrate on which the upper chip structure 200 is mounted, and may include an upper insulating layer 351, upper redistribution layers 352, and an upper redistribution via 353. The upper redistribution via 353 may be electrically connected to the plurality of second posts 320, and may be electrically connected to the plurality of first posts 120 via the connection vias 122. The upper redistribution structure 350 may have features similar to those of the lower redistribution structure 310, and thus the detailed description of the lower redistribution structure 310 may be applied to the upper redistribution structure 350.

In various embodiments, the external connection conductors 360 may be disposed below the lower redistribution structure 310, where the external connection conductors 360 may extend beneath a surface of the lower substrate 311 opposite the lower chip structure. The external connection conductors 360 may be electrically connected to the lower redistribution layer 312. The semiconductor package 10A may be connected to an external device, such as a module substrate or system board, via the external connection conductors 360. The external connection bumps 360 may be in the form of a combination of a pillar (or under-bump metal) and a ball. The pillar may include copper (Cu) or an alloy of copper (Cu), and the ball may include a low melting point metal, for example, tin (Sn) or an alloy (Sn—Ag—Cu) including tin (Sn). In various embodiments, the external connection conductors 360 may include only a pillar or a ball. In various embodiments, a resist layer may be formed on a lower surface of the lower redistribution structure 310 to protect the external connection conductors 360 from physical and chemical damage.

In various embodiments, at least one passive device 365 may be disposed below the lower redistribution structure 310, where the one or more passive devices 365 may extend beneath a surface of the lower substrate 311 opposite the lower chip structure. The passive device 365 may include, for example, a capacitor, an inductor, or beads. The passive device 365 may be flip-chip bonded to the lower surface of the lower redistribution structure 310. The passive device(s) 365 may be electrically connected to the lower redistribution layer 312 via a solder bump or the like. An underfill resin may be filled between the passive device 365 and the lower redistribution structure 310.

In various embodiments, the heat dissipation member 340 may be disposed on the upper redistribution structure 350, where the heat dissipation member 340 may overlap at least a portion of the lower chip structure 100A vertically (for example, in the Z-axis direction). The heat dissipation member 340 may be disposed on one side of the upper chip structure 200, where the heat dissipation member 340 may be laterally spaced apart from the upper chip structure 200. The heat dissipation member 340 may control warpage of the semiconductor package 10A, and may externally dissipate heat generated from the lower chip structure 100A.

In various embodiments, the heat dissipation member 340 may include a thermal interface material (TIM) layer 342 and a heat slug 341. The thermal interface material layer 342 may be in thermal contact with the upper surface 100T of the lower chip structure 100A. The thermal interface material layer 342 may include, for example, a heat conductive adhesive tape, heat conductive grease, or heat conductive adhesive. The heat slug 341 may be disposed on the thermal interface material layer 342. The heat slug 341 may include a material having excellent thermal conductivity, such as aluminum (Al), gold (Au), silver (Ag), copper (Cu), iron (Fe), graphite, or graphene. In various embodiments, an electrically insulating resin may be fill the space between the heat dissipation member 340 and the upper chip structure 200.

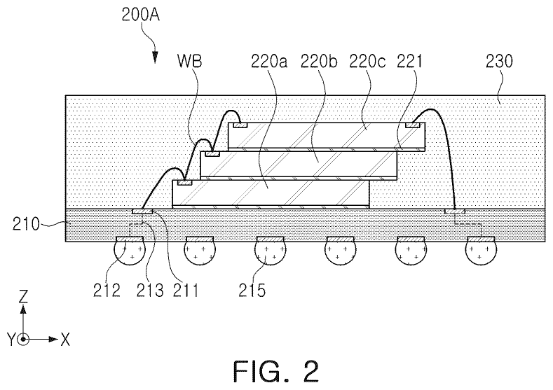

FIG. 2 is a cross-sectional view illustrating an upper chip structure applicable to the semiconductor package 10A of FIG. 1A, according to an embodiment.

Referring to FIG. 2, the upper chip structure 200A according to the example embodiment may include a substrate 210, a plurality of semiconductor chips 220a, 220b, and 220c, and a molding member 230.

In various embodiments, the substrate 210 may be a support substrate on which a plurality of semiconductor chips 220a, 220b, and 220c may be mounted, where the substrate 210 may include a printed circuit board (PCB), a ceramic substrate, a glass substrate, or a tape interconnection line substrate. The substrate 210 may have a lower surface and an upper surface respectively, with a thickness therebetween, including a lower pad 212 and an upper pad 211 thereon, the lower pad 212 and the upper pad 211 electrically connected to features outside the substrate 210. In various embodiments, the substrate 210 may include an interconnection line circuit 213, electrically connecting the lower pad 212 and the upper pad 211 to each other.

In various embodiments, the plurality of semiconductor chips 220a, 220b, and 220c may be mounted on the substrate 210 in a wire bonding manner or a flip-chip bonding manner. The plurality of semiconductor chips 220a, 220b, and 220c may be stacked on the substrate 210 vertically (for example, in a Z-axis direction), where the plurality of semiconductor chips 220a, 220b, and 220c may be stacked sequentially on top of each other, and may be electrically connected to the upper pad 211 of the substrate 210 by a bonding wire WB. The stack of semiconductor chips 220a, 220b, and 220c may laterally offset from each other. The plurality of semiconductor chips 220a, 220b, and 220c may include volatile and/or non-volatile memory chips.

In various embodiments, the molding member 230 may cover at least a portion of the plurality of semiconductor chips 220a, 220b, and 220c, on the substrate 210. The molding member 230 may include a material the same as or similar to that of the first encapsulants 142 and the second encapsulant 330 described above. Connection bumps 215 may be disposed below the substrate 210. The connection bumps 215 may be electrically connected to the plurality of semiconductor chips 220a, 220b, and 220c via the interconnection line circuit 213 and the upper pad 211. The connection bumps 215 may include, for example, tin (Sn) or an alloy (for example, Sn—Ag—Cu) including tin (Sn). The upper chip structure 200A, described above with reference to FIG. 2, may not be limited thereto.

FIG. 3 is a cross-sectional view illustrating a semiconductor package 10B according to an example embodiment of the present inventive concept.

Referring to FIG. 3, the semiconductor package 10B, according to an embodiment, may have features the same as or similar to those described with reference to FIGS. 1A to 2, except that a back surface BS of the first semiconductor chip 100a includes a lower chip structure 100B adjacent to an upper surface of a lower redistribution structure 310. The first semiconductor chip 100a may include a substrate 101, a circuit layer 110 disposed on the substrate 101, and a lower protective layer 106 disposed below the substrate 101. The first semiconductor chip 100a may have a front surface FS and a back surface BS, opposing each other with a thickness therebetween. The front surface FS of the first semiconductor chip 100a, may be a surface adjacent to an active surface of the substrate 101, and may refer to an upper surface of the circuit layer 110. The back surface BS of the first semiconductor chip 100a, may be a surface adjacent to an inactive surface of the substrate 101, and may refer to a lower surface of the lower protective layer 106, where the back surface BS may be proximal to the lower redistribution structure 310. Through-vias 130 may pass through the substrate 101 and the lower protective layer 106, and may be electrically connected to a first connection terminal 100P. Connection pads 121 may be disposed on the circuit layer 110. In an embodiment, the connection pads 121 may not be electrically connected to the through-vias 130.

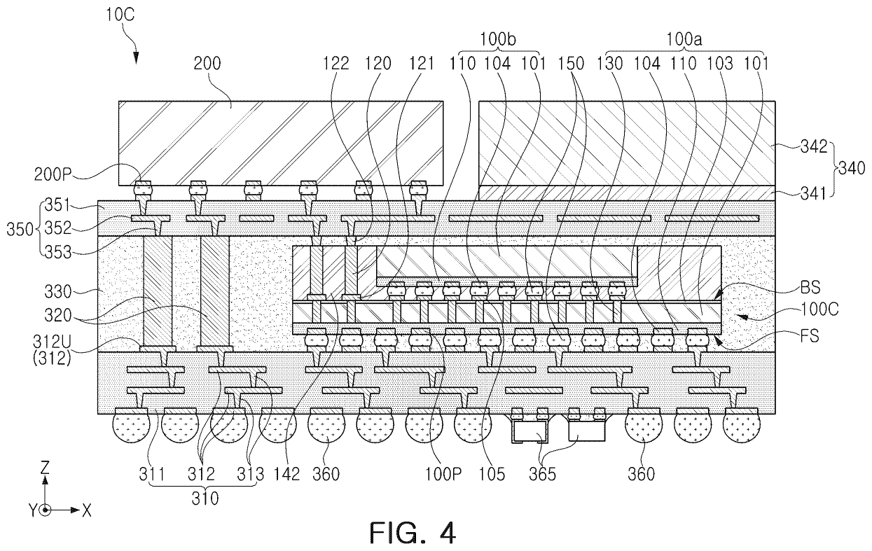

FIG. 4 is a cross-sectional view illustrating a semiconductor package 10C, according to an embodiment of the present inventive concept.

Referring to FIG. 4, the semiconductor package 10C, according to an embodiment, may have features the same as or similar to those described with reference to FIGS. 1A to 3, except that connection bumps 150, connecting a first semiconductor chip 100a and a second semiconductor chip 100b to each other, may include a lower chip structure 100C surrounded by a first encapsulant 142. No underfill may be present between the first semiconductor chip 100a and the second semiconductor chip 100b, and the lower chip structure 100C, filled with the first encapsulant 142 in the form of a molded underfill (MUF), may be included. The first encapsulant 142 may cover at least a portion of the connection bumps 150 disposed between the first semiconductor chip 100a and the second semiconductor chip 100b.

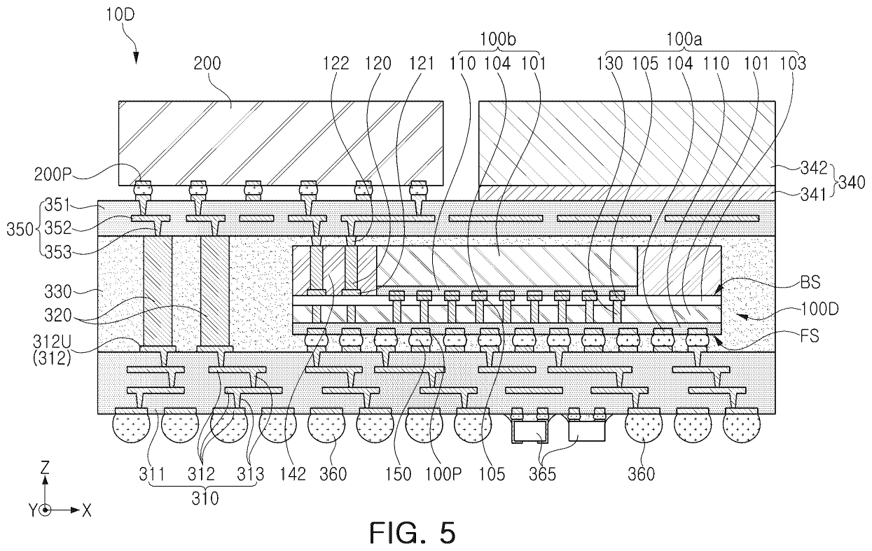

FIG. 5 is a cross-sectional view illustrating a semiconductor package 10D according to an example embodiment of the present inventive concept.

Referring to FIG. 5, the semiconductor package 10D according to an example embodiment may have features the same as or similar to those described with reference to FIGS. 1A to 4, except that a lower chip structure is included in which a first semiconductor chip 100a and a second semiconductor chip 100b are bonded to each other using metal bonding. The lower chip structure 100D may include a plurality of semiconductor chips 100a and 100b, directly bonded to each other and coupled to each other without a connection member (for example, a solder bump, a copper post, or the like). The lower chip structure 100D may have a bonding surface on which an upper surface of the first semiconductor chip 100a and a lower surface of the second semiconductor chip 100b are bonded to each other. The bonding surface may be formed using metal bonding or dielectric bonding. For example, upper pads 105 of the first semiconductor chip 100a and lower pads 104 of the second semiconductor chip 100b may include a material that may be bonded to each other and accordingly coupled to each other, for example, copper (Cu), nickel (Ni), titanium (Ti), or alloys thereof. An upper protective layer 103 of the first semiconductor chip 100a and a circuit layer 110 of the second semiconductor chip 100b, forming the bonding surface, may include a material that may be bonded to each other and accordingly coupled to each other, for example, at least one of silicon oxide (SiO), silicon nitride (SiN), or silicon carbonitride (SiCN).

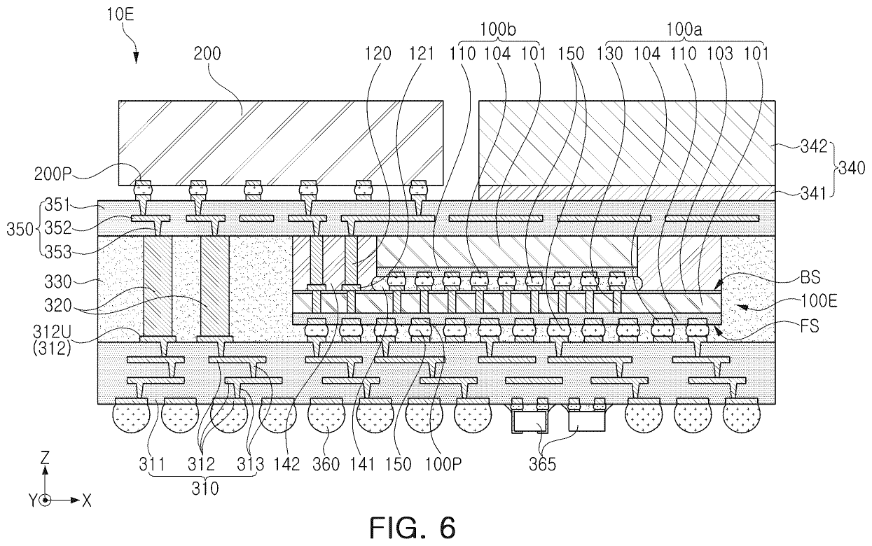

FIG. 6 is a cross-sectional view illustrating a semiconductor package 10E according to an example embodiment of the present inventive concept.

Referring to FIG. 6, the semiconductor package 10E, according to an embodiment, may have features the same as or similar to those described with reference to FIGS. 1A to 5, except that a lower chip structure 100E and an upper redistribution structure 350 are in contact with each other. In an embodiment, a second encapsulant 330 may be disposed to surround a side surface of each of the lower chip structure 100E and a plurality of second posts 320 without being interposed between the lower chip structure 100E and the upper redistribution structure 350. An upper surface of the lower chip structure 100E and a lower surface of the upper redistribution structure 350 may be in direct contact with each other, and upper surfaces of a plurality of first posts 120 may be respectively in direct contact with lower surfaces of upper redistribution vias 353. The plurality of first posts 120 may be directly electrically connected to the upper redistribution vias 353, respectively. A level of an uppermost end (surface) of each of the plurality of second posts 320 may be the same as an uppermost level of each of the plurality of first posts 120, and a level of an uppermost end (surface) of the second encapsulant 330 may be the same as a level of an uppermost end (surface) of the first encapsulant 142, where an upper surface of the second posts 320, second encapsulant 330, first posts 120, and first encapsulant 142 may be coplanar.

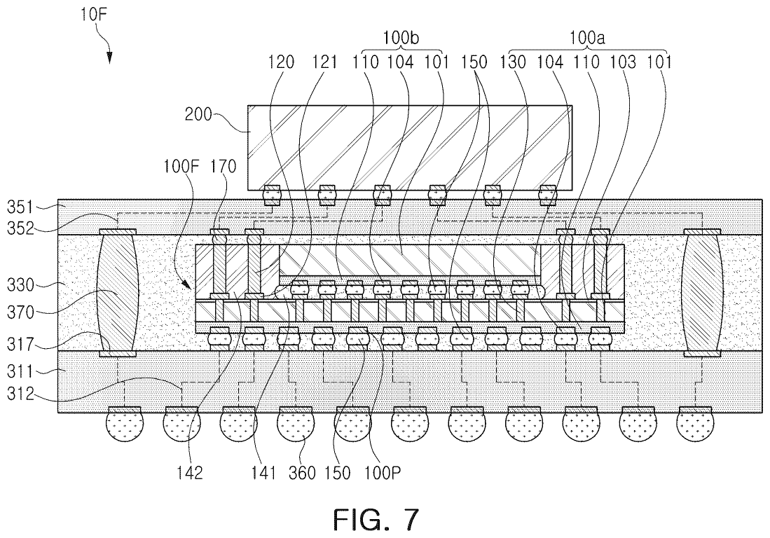

FIG. 7 is a cross-sectional view illustrating a semiconductor package 10F according to an example embodiment of the present inventive concept.

Referring to FIG. 7, the semiconductor package 10F, according to an,embodiment, may have features the same as or similar to those described with reference to FIGS. 1A to 6, except that a connection structure 370 is further included, and a plurality of first posts 120 are disposed on both sides of a second semiconductor chip 100b. A lower substrate 311 may be a substrate on which a lower chip structure 100F is mounted, and an upper substrate 351 may be an interposer substrate. The connection structure 370 may pass through a second encapsulant 330, and may electrically connect the lower substrate 311 and the upper substrate 351 to each other. The connection structure 370 may include copper (Cu) and/or an alloy of copper (Cu). A seed layer may be disposed on a lower portion of the connection structure 370. The seed layer may include at least one of titanium (Ti), an alloy of titanium (Ti), copper (Cu), oran alloy of copper (Cu).

In various embodiments, he plurality of first posts 120 may be electrically connected to redistribution pads 312U and an upper redistribution circuit layer 352 via upper bumps 170, respectively. Each of the plurality of first posts 120 may be disposed on connection pads 121 of a first semiconductor chip 100a, and may be disposed on both sides of the second semiconductor chip 100b, where the first posts 120 may be spaced apart from each other. At least a portion of the plurality of first posts 120 may be disposed to overlap an upper chip structure 200 in a vertical direction (for example, Z-axis direction). Accordingly, the number of shortened data signal transmission paths of the upper chip structure 200 may increase.

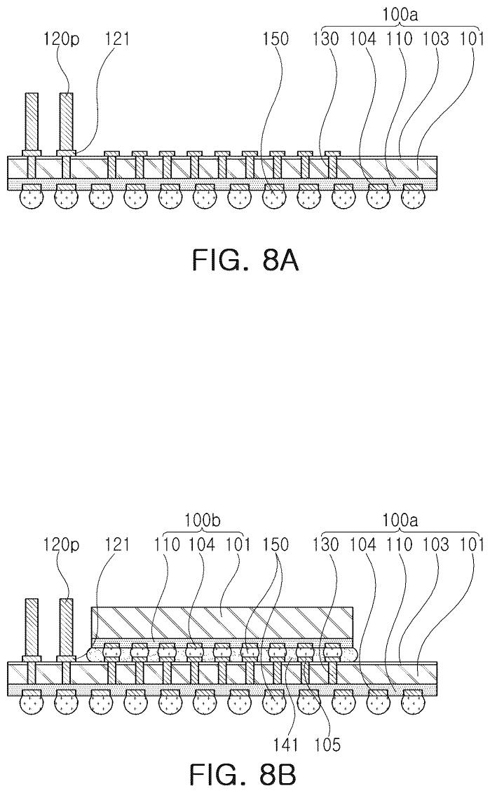

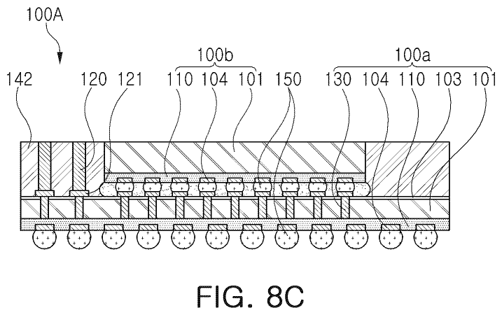

FIGS. 8A to 8C are schematic cross-sectional views illustrating a process of manufacturing a lower chip structure of a semiconductor package, according to an example embodiment of the present inventive concept.

Referring to FIG. 8A, a first semiconductor chip 100a and a plurality of preliminary first posts 120p may be formed, where the preliminary first posts 120p may be formed on the first semiconductor chip 100a. The first semiconductor chip 100a may include a substrate 101, an upper protective layer 103 disposed on the substrate 101, a circuit layer 110 disposed below the substrate 101, and through-vias 130 passing through the upper protective layer 103 and the substrate 101. Connection pads 121 may be disposed on the first semiconductor chip 100a, and may be electrically connected to at least one through via 130, where the connection pads 121 may be on the upper protective layer 103.

In various embodiments, the plurality of preliminary first posts 120p may be formed on the connection pads 121. A seed layer may be formed on upper surfaces of the connection pads 121 and the first semiconductor chip 100a, and the preliminary first posts 120p may be formed on the connection pads 121 using a photoresist film. In an embodiment, the preliminary first posts 120p may be formed by plating copper (Cu). The preliminary first posts 120p may be formed to extend in a direction, perpendicular to the upper surfaces of the connection pads 121.

Referring to FIG. 8B, a second semiconductor chip 100b may be attached to the first semiconductor chip 100a. An upper pad 105 of the first semiconductor chip 100a and a lower pad 104 of the second semiconductor chip 100b may be connected to each other via a connection bump 150 disposed therebetween, where the upper pad 105, connection bump 150, and lower pad 104 can form an electrical connection between the first semiconductor chip 100a and the second semiconductor chip 100b. An underfill 141, surrounding the connection bumps 150, may be formed between the first semiconductor chip 100a and the second semiconductor chip 100b, using a thermal curing process. An upper surface of the second semiconductor chip 100b may be disposed on a level lower than or the same as that of an uppersurface of the preliminary first posts 120p. A process of attaching the second semiconductor chip 100b to the first semiconductor chip 100a may be in the form of several lower chip structures 100C and 100D, in some example embodiments.

Referring to FIG. 8C, a lower chip structure 100A on which a first encapsulant 142 is disposed may be formed. The first semiconductor chip 100a may be covered with an encapsulating material, and then the encapsulating material may be cured to form the first encapsulant 142. The first encapsulant 142 may cover at least a portion of each of the first semiconductor chip 100a, the second semiconductor chip 100b, and a plurality of first posts 120. The first encapsulant 142 may be formed, for example, by applying and curing an epoxy molding compound (EMC). An upper portion of the first encapsulant 142 may be flattened using a polishing device, where a planarization process may include a grinding process, a chemical mechanical polishing (CMP) process, and the like. The first posts 120 may be formed by removing at least a portion of the preliminary first posts 120p using the planarization process. Upper surfaces of the plurality of first posts 120 and an upper surface of the lower chip structure 100A may be exposed at an upper surface of the first encapsulant 142. Accordingly, a flat surface including the upper surface of the first encapsulant 142, the upper surfaces of the plurality of first posts 120, and the upper surface of the lower chip structure 100A may be formed.

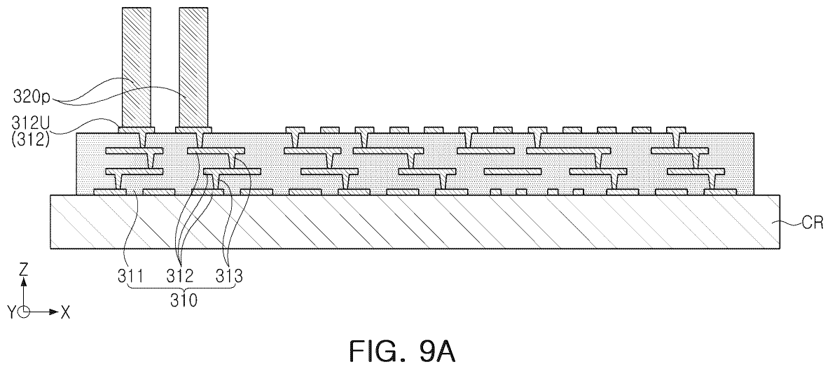

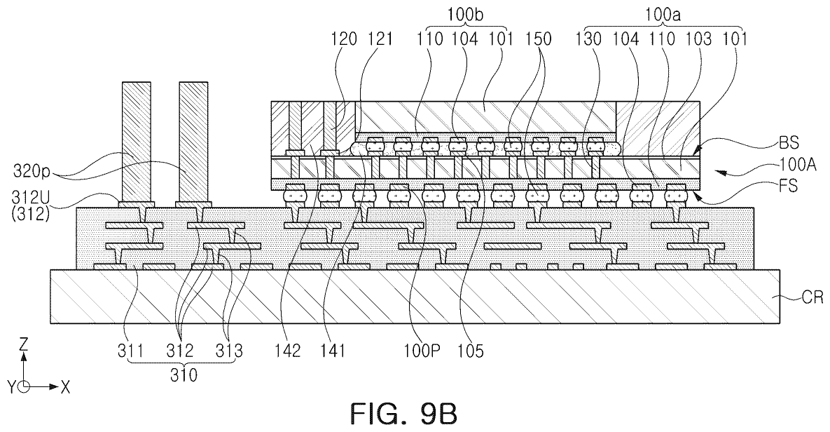

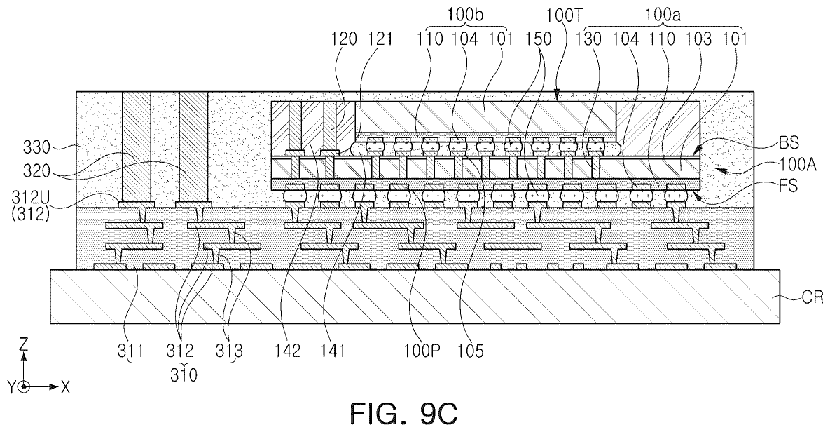

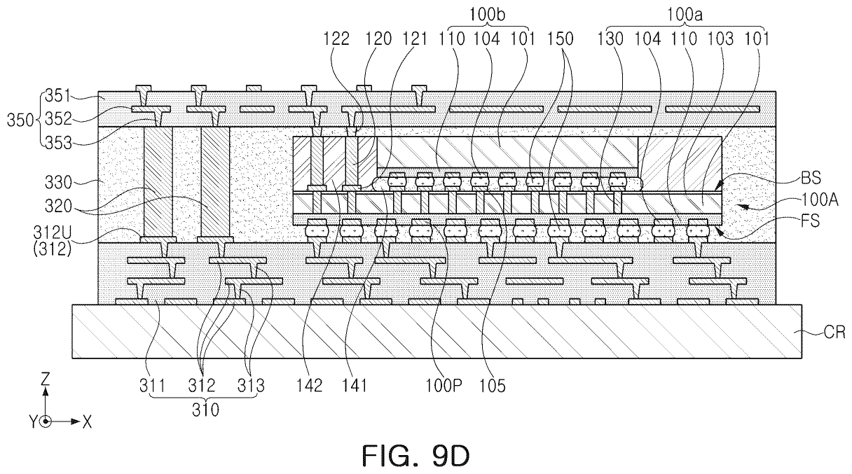

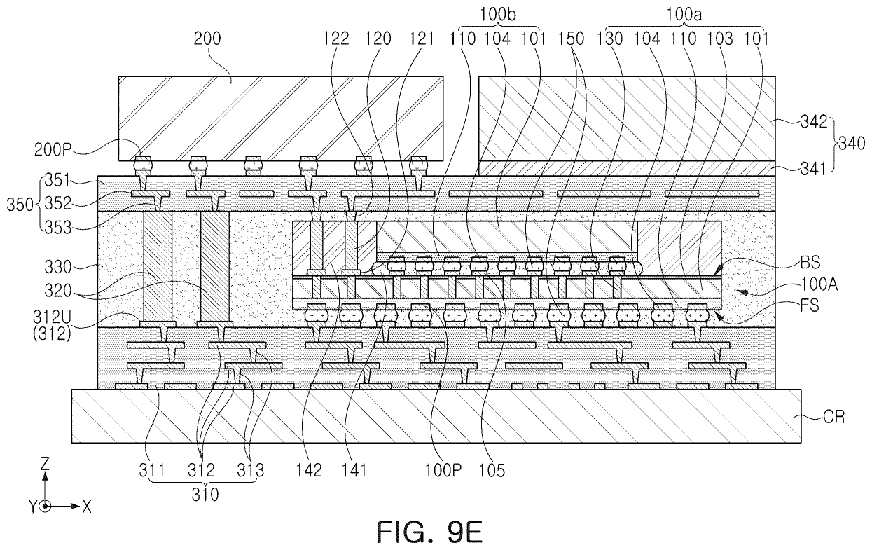

FIGS. 9A to 9E are schematic cross-sectional views illustrating a process of manufacturing a semiconductor package, according to an embodiment of the present inventive concept.

Referring to FIG. 9A, a lower redistribution structure 310 and preliminary second posts 320p may be formed on a carrier substrate CR.

In various embodiments, the carrier substrate CR may include a copper clad laminate (CCL) sequentially coated with a polymer layer, including a curable resin and a metal layer including nickel (Ni) and titanium (Ti).

In various embodiments, a lower redistribution structure 310 may include a lower insulating layer 311, a lower redistribution layer 312, and a lower redistribution via 313. The lower insulating layer 311 may be formed by sequentially applying and curing a photosensitive material, for example, a PID. The lower redistribution layer 312 and the lower redistribution via 313 may be formed by performing an exposure process and a development process to form a via hole, passing through the lower insulating layer 311, and patterning a metal material on the lower insulating layer 311 using a plating process. A redistribution pad 312U may be formed on an upper surface of the lower redistribution structure 310, where the redistribution pad 312U may be formed on the lower insulating layer 311. A barrier layer including nickel (Ni) and gold (Au) may be formed on the redistribution pad 312U. A plurality of preliminary second posts 320p may have features the same as or similar to those of a plurality of preliminary first posts 120p, and thus the detailed description of the process for forming the preliminary first posts 120p may be applied to forming the plurality of preliminary second posts 320p.

Referring to FIG. 9B, a lower chip structure 100A may be mounted on the lower redistribution structure 310, where the lower chip structure 100A may be mounted on the lower redistribution structure 310 in a flip-chip manner. The lower chip structure 100A may be connected to the redistribution pad 312U via a lower connection bump 150 formed on a first connection terminal 100P. In various embodiments, an underfill may be formed between the lower chip structure 100A and the lower redistribution structure 310. The underfill may be formed using a CUF process, but the present inventive concept is not limited thereto.

Referring to FIG. 9C, a second encapsulant 330, covering at least a portion of each of the lower chip structure 100A and second posts 320, may be formed, where the second encapsulant 330 may seal the lower chip structure 100A. The second encapsulant 330 may have features the same as or similar to those of the first encapsulant 142, and thus the detailed description of a process of forming the first encapsulant 142 may be applied to forming the second encapsulant 330. At least a portion of the second encapsulant 330 may be disposed to cover an upper surface of the lower chip structure 100A.

Referring to FIG. 9D, an upper redistribution structure 350, including connection vias 122 and an upper redistribution layer 352, may be formed. A via hole may be formed by removing a portion of the second encapsulant 330, overlapping the plurality of first posts 120, in a direction, perpendicular to the upper surfaces of the plurality of first posts 120. The via hole may be formed using a physical process using a laser. Connection vias 122 may be formed in the via hole using a plating process. At least a portion of lower surfaces of the connection vias 122 may be in electrical contact with the upper surfaces of the plurality of first posts 120.

In various embodiments, the upper redistribution structure 350 may be formed on the second encapsulant 330, the plurality of second posts 320, and the connection vias 122. The upper redistribution vias 353 may be positioned to align with the plurality of second posts 320 or the connection vias 122, where the upper redistribution vias 353 may form electrical connections with the second posts 320 and/or the connection vias 122. The upper redistribution vias 353 may be electrically connected to the plurality of second posts 320 or connection vias 122.

Referring to FIG. 9E, a heat dissipation member 340 and an upper chip structure 200 may be disposed on the upper redistribution structure 350. The heat dissipation member 340 may be attached to the upper redistribution structure 350 and a lower chip structure 100A by a thermal interface material layer 342. The heat dissipation member 340 may be positioned to vertically overlap at least a portion of the lower chip structure 100A. The upper chip structure 200 may be electrically connected to a plurality of posts 320 in a flip-chip manner. At least a portion of the upper chip structure 200 may be positioned to overlap the plurality of first posts 120 in a vertical direction (for example, Z-axis direction). In various embodiments, an electrically insulating material layer, such as an underfill may be formed below the upper chip structure 200, where the underfill may be interposed between the upper chip structure 200 and the upper redistribution structure 350.

Referring to FIGS. 1A and 1B, external connection bumps 360 and passive devices 365 may be formed below the lower redistribution structure 310. The external connection bumps 360 may be attached to a lower redistribution layer 312. The passive devices 365 may be flip-chip mounted on the lower redistribution layer 312.

According to the various embodiments of the present inventive concept, conductive posts, passing through at least a portion of a lower chip structure, may be introduced, thereby providing a semiconductor package having improved reliability.

While non-limiting example embodiments have been shown and described above, it will be apparent to those skilled in the art that modifications and variations could be made without departing from the scope of the present inventive concept as encompassed by the appended claims.

What is claimed is:

1. A semiconductor package comprising:
a lower redistribution structure including a lower redistribution layer;
a lower chip structure on the lower redistribution structure, the lower chip structure including a first semiconductor chip electrically connected to the lower redistribution layer, a second semiconductor chip on the first semiconductor chip, a plurality of first posts on at least one side of the second semiconductor chip and electrically connected to the first semiconductor chip, and a first encapsulant covering at least a portion of each of the first semiconductor chip, the second semiconductor chip, and the plurality of first posts;
a plurality of second posts on the lower redistribution structure, wherein the plurality of second posts are on at least one side of the lower chip structure and electrically connected to the lower redistribution layer;
a second encapsulant covering at least a portion of the lower chip structure and each of the plurality of second posts;
connection vias passing through a portion of the second encapsulant covering an upper portion of the lower chip structure, wherein the connection vias respectively electrically connected to the plurality of first posts;
an upper redistribution structure on the second encapsulant, the upper redistribution structure including an upper redistribution layer and upper redistribution vias electrically connecting the upper redistribution layer and the connection vias to each other;
an upper chip structure on the upper redistribution structure and electrically connected to the upper redistribution layer; and
external connection conductors on the lower redistribution structure and electrically connected to the lower redistribution layer.

2. The semiconductor package of claim 1, wherein the connection vias have a shape that tapers toward the plurality of first posts.

3. The semiconductor package of claim 2, wherein a width of a lower surface of each of the connection vias in a horizontal direction is less than a width of an upper surface of each of the plurality of first posts in the horizontal direction.

4. The semiconductor package of claim 1, wherein at least one of the first or second semiconductor chips includes a logic chip.

5. The semiconductor package of claim 1, wherein
the upper chip structure includes a plurality of semiconductor chips, wherein the plurality of semiconductor chips are vertically stacked on each other, and
the plurality of semiconductor chips include at least one memory chip.

6. The semiconductor package of claim 1, wherein the plurality of first posts overlap the upper chip structure in a direction perpendicular to an upper surface of the lower redistribution structure.

7. The semiconductor package of claim 1, further comprising:
a heat dissipation member adjacent to the upper chip structure, on the upper redistribution structure.

8. The semiconductor package of claim 1, wherein the lower chip structure further includes connection bumps disposed between the first and second semiconductor chips and an underfill covering at least a portion of each of the connection bumps.

9. The semiconductor package of claim 1, wherein
the first semiconductor chip further includes upper pads,
the second semiconductor chip further includes lower pads, and
the upper pads and lower pads, corresponding to each other, are metal-bonded to each other.

10. The semiconductor package of claim 1, wherein the plurality of first posts are disposed on both sides, opposite to each other, of the second semiconductor chip.

11. The semiconductor package of claim 1, wherein the plurality of first and second posts include copper (Cu).

12. A semiconductor package comprising:
a lower redistribution structure;
a lower chip structure including a first semiconductor chip on the lower redistribution structure, a second semiconductor chip on the first semiconductor chip, a first encapsulant surrounding the second semiconductor chip, and a plurality of first posts passing through the first encapsulant, the plurality of first posts electrically connected to the first semiconductor chip;
a second encapsulant on the lower redistribution structure and surrounding the lower chip structure;
a plurality of second posts passing through the second encapsulant, wherein the plurality of second posts are electrically connected to the lower redistribution structure;
an upper redistribution structure on the second encapsulant; and
an upper chip structure mounted on the upper redistribution structure,
wherein the plurality of first posts provide a transmission path for a signal between the lower chip structure and the upper chip structure.

13. The semiconductor package of claim 12, wherein
the plurality of first posts provide a transmission path for at least one of a data signal, a command signal, an address signal, or a ground signal of the upper chip structure, and
the plurality of second posts provide a transmission path for a power signal to the upper chip structure.

14. The semiconductor package of claim 12, wherein
the first encapsulant includes a first filler,
the second encapsulant includes a second filler, and
an average diameter of the first filler is less than an average diameter of the second filler.

15. The semiconductor package of claim 12, wherein a length of each of the plurality of first posts is less than a length of each of the plurality of second posts.

16. The semiconductor package of claim 12, wherein an upper surface of the first encapsulant is coplanar with an upper surface of the second encapsulant and upper surfaces of the plurality of second posts.

17. A semiconductor package comprising:
a lower redistribution structure;
a lower chip structure including a plurality of semiconductor chips on the lower redistribution structure and a plurality of first posts on a lowermost semiconductor chip, among the plurality of semiconductor chips, wherein the plurality of first posts are spaced apart from chips other than the lowermost semiconductor chip;
a plurality of second posts on the lower redistribution structure;
an encapsulant covering at least a portion of each of the lower chip structure and the plurality of second posts; and
an upper chip structure disposed on the encapsulant and electrically connected to the plurality of first posts and second posts,
wherein a level of an uppermost end of each of the plurality of first posts is lower than a level of an uppermost end of each of the plurality of second posts.

18. The semiconductor package of claim 17, wherein a diameter of each of the plurality of first posts is about 30 micrometers (μm) or less.

19. The semiconductor package of claim 17, wherein a diameter of each of the plurality of second posts is about 30 μm or more.

20. The semiconductor package of claim 17, wherein at least a portion of the plurality of semiconductor chips includes through-vias electrically connecting the plurality of semiconductor chips to each other.
